(19) United States
(12) Patent Application Publication
(10) Pub. No.: US 2007/0182448 A1
(43) Pub. Date: Aug. 9, 2007

(54) Level shifter for flat panel display device

(76) Inventors: Oh Kyong Kwon, Seoul (KR); Byong Deok Choi, Seoul (KR)

Correspondence Address: CHRISTIE, PARKER & HALE, LLP, PO BOX 7068, PASADENA, CA, 91109-7068, US

(21) Appl. No.: 11/601,479

(22) Filed: Nov. 17, 2006

(30) Foreign Application Priority Data
Jan. 20, 2006 (KR) 10-2006-0006251
Jan. 20, 2006 (KR) 10-2006-0006254

(51) Int. Cl. H03K 19/094

(52) U.S. Cl. 326/68

(57) ABSTRACT

A level shifter for a flat panel display device is provided. The level shifter includes a first transistor coupled with a first power supply and having a gate and a drain are coupled together; and a capacitor coupled between an input voltage terminal and a first node coupled with the drain of the first transistor. The level shifter also includes a second transistor coupled with the first node to reset the capacitor; and a third transistor coupled to the first node, and coupled between a second power supply and an output voltage terminal. The level shifter also includes a fourth transistor to the first node, and coupled between an inverse input voltage terminal and the output voltage terminal.

### CROSS-REFERENCE TO RELATED APPLICATIONS

This application claims priority to and the benefit of Korean Patent Application Nos. 10-2006-0006251 and 10-2006-0006254, filed on Jan. 20, 2006, in the Korean Intellectual Property Office, the entire contents of both of which are incorporated herein by reference.

### BACKGROUND

1. Field of the Invention

The present invention relates to a level shifter, and in particular, to a level shifter for a, flat panel display device.

2. Discussion of Related Art

Recently, flat panel display devices capable of having a reduced weight and volume have been developed.

Generally, the flat panel display devices are realized in an active matrix type having a pixel array arranged in a matrix shape cross-linking parts between data lines and scan lines. As a result, the scan lines are horizontal lines (row lines) of the matrix pixel array, and the horizontal lines (row lines) sequentially supply a predetermined signal, namely a scan signal from a scan driver circuit to each pixel of the pixel array.

Also, the data lines include vertical lines (column lines) of the matrix pixel array, and the vertical lines (column lines) sequentially supply a predetermined data signal from the data driver circuit, wherein the data signal is synchronized with the scan signal, to each pixel of the pixel array.

The scan driver circuit includes a plurality of gate shift registers in which outputs are individually coupled to a plurality of level shifters. The plurality of the gate shift registers shift an input gate start pulse (GSP) to sequentially supply the shift pulse to the level shifters. The level shifters enhance a swing voltage for the shift pulse from the gate shift registers to supply a scan signal to the scan lines.

Also, the data driver circuit includes a plurality of data shift registers and sampling switches in which outputs are individually contacted to a plurality of level shifters. The data shift registers shift an input data start pulse (DSP) to sequentially supply a shift signal to the level shifters, and the level shifters are individually coupled between the data shift registers and the sampling switches to enhance their swing voltage for the shift pulse from the data shift registers, thereby to supply a sampling signal to the sampling switches. As a result, the sampling switches sequentially sample the video signal, into which their outputs are individually contacted to the data lines and input in response to a sampling signal, to supply the sampled video signal to the data lines.

The level shifter provided in the flat panel display device functions to enhance a swing width of the input pulse because a pulse having a swing voltage greater than a certain width should be supplied so as to drive thin film transistors of each pixel provided in the pixel array of the flat panel display device.

### SUMMARY OF THE INVENTION

In one embodiment of the present invention, a level shifter for a flat panel display device is provided. The level shifter includes: a first transistor coupled with a first power supply, the first transistor having a gate and a drain that are coupled together; and a capacitor coupled between an input voltage terminal and a first node coupled with the drain of the first transistor. The level shifter also includes a second transistor coupled with the first node and adapted to reset the capacitor; a third transistor having a gate coupled to the first node, wherein the third transistor is coupled between a second power supply and an output voltage terminal; and a fourth transistor having a gate coupled to the first node, and wherein the fourth transistor is coupled between an inverse input voltage terminal and the output voltage terminal.

In various embodiments, the first transistor is a diode-connected P-channel transistor or an N-channel transistor.

In some embodiments of the level shifter, the second transistor includes: a gate adapted to receive a reset pulse; a source coupled to a ground; and a drain coupled to the first node.

In various embodiments, the third transistor and the fourth transistor are different types of transistors.

In some embodiments of the level shifter, a source of the third transistor is coupled to the second power supply; a source of the fourth transistor is coupled to the inverse input voltage terminal; and a drain of the third transistor and a drain of the fourth transistor are coupled to the output voltage terminal.

In various embodiments, the second power supply has a voltage value that is about twice that of the first power supply.

In a second embodiment of the present invention, a level shifter for a flat panel display device is provided. The level shifter includes: a first transistor coupled with a ground voltage or a power supply, and having a gate and a drain coupled together; a capacitor coupled between an input voltage terminal and a first node coupled with the drain of the first transistor; a second transistor coupled between the first node and the ground voltage or the power supply to reset the capacitor; a third transistor having a gate coupled to the first node, wherein the third transistor is coupled between the third power supply and an output voltage terminal; and a fourth transistor having a gate coupled to the first node, wherein the fourth transistor is coupled between an inverse input voltage terminal and the output voltage terminal.

In various embodiments, the first transistor is a diode-connected N-channel transistor or a P-channel transistor.

In some embodiments, the second transistor includes: a gate adapted to receive a reset pulse; a source coupled with the ground voltage or the power supply; and a drain coupled to the first node.

In some embodiments, the third transistor and the fourth transistor are different types of transistors.

In various embodiments of the level shifter, a source of the third transistor is coupled to the third power supply; a source of the fourth transistor is coupled to the inverse input voltage terminal; and a drain of the third transistor and a drain of the fourth transistor are coupled to the output voltage terminal. In some embodiments, the power supply has a negative voltage value.

In another embodiment of the present invention, a level shifter for a flat panel display device is provided. The level shifter includes: an initial charging part; and a plurality of level shifter parts individually coupled with the initial charging part. The level shifter part includes: a first transistor having a gate adapted to receive a signal output from the initial charging part; a capacitor coupled between an input voltage and a first node to which a drain of the first transistor is coupled; a second transistor having a gate coupled to the first node, wherein the second transistor is coupled between a first power supply and an output voltage terminal; and a third transistor having a gate coupled to the first node, wherein the third transistor is coupled between an inverse input voltage terminal and the output voltage terminal.

In some embodiments, a source of the first transistor is coupled with a second power supply. In some embodiments, the second power supply outputs a positive voltage lower than that of the first power supply.

In various embodiments, the third transistor and the fourth transistor are different types of transistors.

In some embodiments, in the level shifter: a source of the third transistor is coupled to the first power supply; a source of the fourth transistor is coupled to the inverse input voltage terminal; and a drain of the third transistor and a drain of the fourth transistor are coupled to the output voltage terminal.

In some embodiments, the initial charging part includes: a level-up circuit part for receiving the reset signal and the inverse reset signal to level up to a predetermined voltage and output the reset signal and the inverse reset signal; and a buffer part for stabilizing an output voltage of the level-up circuit part.

In some embodiments, the level-up circuit part includes: a first N-channel transistor and a second N-channel transistor for receiving a reset signal and an inverse reset signal; and a latch circuit for leveling up the input voltage, wherein the latch circuit includes a first P-channel transistor and a second P-channel transistor.

In another embodiment of the present invention, a level shifter for a flat panel display device is provided. The level shifter includes: an initial charging part; and a plurality of level shifter parts individually coupled with the initial charging part. Each of the level shifter parts includes: a first transistor having a gate adapted to receive a signal output from the initial charging part; a capacitor coupled between an inverse input voltage terminal and a first node coupled to a drain of the first transistor; a second transistor having a gate coupled to the first node, wherein the second transistor is coupled between a first power supply and an output voltage terminal; and a third transistor having a gate coupled to the first node, wherein the third transistor is coupled between an input voltage terminal and the output voltage terminal.

In some embodiments, a source of the first transistor is coupled with the first power supply. In various embodiments, the third transistor and the fourth transistor are different types of transistors.

In some embodiments of the level shifter, a source of the third transistor is coupled to the second power supply; a source of the fourth transistor is coupled to the input voltage terminal; and a drain of the third transistor and a drain of the fourth transistor are coupled to the output voltage terminal.

In some embodiments, the initial charging part includes: a level-up circuit part for receiving a reset signal and an inverse reset signal to level up to a predetermined voltage and output the reset signal and the inverse reset signal; and a buffer part for stabilizing an output voltage of the level-up circuit part.

In another embodiment of the present invention, a level shifter for a flat panel display device is provided. The level shifter includes: an initial charging part including: a level-up circuit part for receiving a reset signal and an inverse reset signal to level up to a predetermined voltage and output the reset signal and the inverse reset signal; and a buffer part for stabilizing an output voltage of the level-up circuit part; and a plurality of level shifter parts individually coupled with the initial charging part. The level shifter parts includes: a first transistor having a gate adapted to receive a signal output from each of the initial charging parts, wherein the first transistor is coupled between a first node and a ground voltage or a power supply; a capacitor coupled between the first node and an input voltage terminal or an inverse input voltage terminal; a second transistor in which the gate is coupled to the first node, wherein the second transistor is coupled between a power supply and an output voltage terminal; and a third transistor having a gate coupled to the first node, and coupled at a first end between the inverse input voltage or the input voltage terminal and coupled at a second end to the output voltage terminal.

### BRIEF DESCRIPTION OF THE DRAWINGS

FIGS. 1A and 1B are circuit diagrams showing configurations of a conventional level up shifter and a conventional level down shifter, respectively.

FIG. 2 is a circuit diagram showing a level shifter according to the first embodiment of the present invention.

FIGS. 3A and 3B are circuit diagrams illustrating an operation of the level shifter circuit as shown in FIG. 2.

FIGS. 4A and 4B are diagrams showing an operation characteristic of the level shifter circuit as shown in FIG. 2.

FIGS. 5A, 5B, 5C and 5D are circuit diagrams showing a level shifter according to the second embodiment of the present invention.

FIGS. 6A and 6B are circuit diagrams showing a level shifter according to the third embodiment of the present invention.

FIGS. 7A, 7B and 7C are circuit diagrams illustrating an operation of the level shifter circuit as shown in FIG. 6A.

FIGS. 8A, 8B and 8C are circuit diagrams illustrating an operation of the level shifter circuit as shown in FIG. 6B.

FIGS. 9A and 9B are circuit diagrams showing a level shifter according to the fourth embodiment of the present invention.

### DETAILED DESCRIPTION

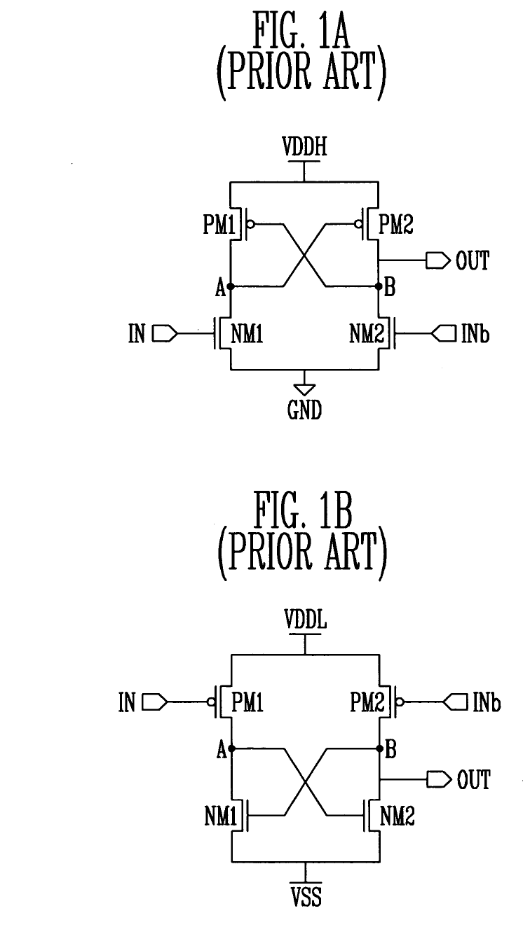

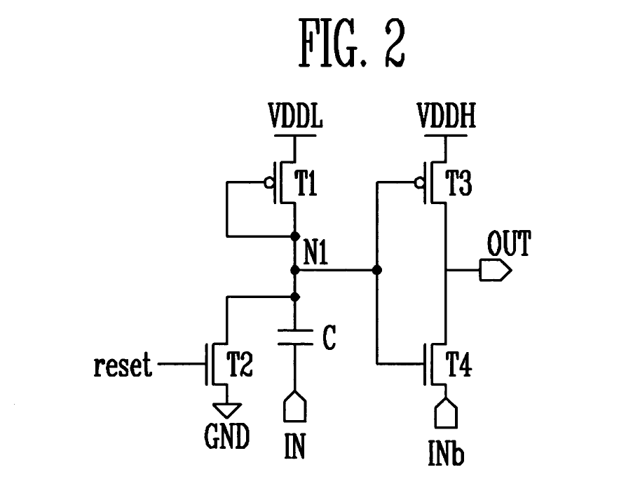

FIG. 1A is a circuit diagram showing a configuration of a conventional level up shifter, and FIG. 1B is a circuit diagram showing a configuration of a conventional level down shifter.

VDDH, as shown in FIG. 1A, represents a supply voltage of the level up shifter; VDDL and VSS, as shown in FIG. 1B represent a supply voltage of the level down shifter; IN represents an input voltage terminal of the level up/down shifters wherein the IN receives an input voltage; and OUT represents an output voltage terminal of the level up/down shifters wherein the OUT outputs an output voltage.

Hereinafter, a configuration and an operation of the level up shifter will be described in detail with reference to FIG. 1A. Referring to FIG. 1A, the conventional level up shifter includes first and second N-channel transistors (NM1, NM2) for receiving an input voltage and an inverse input voltage, respectively; and a latch circuit for leveling up the input voltage. The latch circuit includes the first and second P-channel transistors (PM1, PM2).

In the transistors NM1, NM2, a gate is coupled with an input voltage terminal (IN) and an inverse input voltage terminal (INb), respectively, a source is coupled with a ground voltage (GND), and a drain is contacted with a first and second nodes (A, B), respectively, thereby being coupled to the latch circuit. Further, the second node (B) is coupled with an output voltage terminal (OUT). The gate and drain of transistors PM1, PM2 making up the latch circuit are cross-linked to be coupled between the first and second nodes, respectively, and the source for PM1, PM2 is coupled to a supply voltage VDDH of the level up shifter.

In the case of the conventional level up shifter having this configuration, in one embodiment, if an input voltage, which is input at IN, ranges from 0 V to 5 V, and an output voltage, which is output from OUT, ranges, from 0 V to 10 V, then an inverse voltage, which is input at INb, is at a low level, namely 0 V when the input voltage is at a high level, namely 5 V, and the inverse voltage is at a high level (5 V) when the input voltage is at a low level (0 V).

If the input voltage is 5 V, then NM1 to which the input voltage is applied is turned on, and NM2 to which the inverse input voltage is applied is turned off. Accordingly, PM2 is turned on by the turned-on NM1, and an output voltage is leveled up to 10 V by the supply voltage VDDH.

If the input voltage is 0 V, then NM2 to which the inverse input voltage is applied is turned on, and NM1 to which the input voltage is applied is turned off, therefore the output voltage becomes 0 V.

As known to those of ordinary skill in the art, a level down shifter as shown in FIG. 1B may be operated with similar principles as in the above-mentioned level up shifter.

An operation of the conventional level up shifter will be described, as follows. First, if the input voltage, which is input at IN, makes a transition from a low level (0 V) to a high level (5 V), then the NM1 is turned on, and the NM2 is turned off. As the NM1 is turned on, the first node (A) returns to a low level, and then the PM2 is turned on. Accordingly, the second node (B) returns to a high level, and then the PM1 is turned off.

Accordingly, in some embodiments, a voltage level of the second node (B) may be identical to the level-up voltage, namely VDDH, and this voltage (10 V) may be supplied to the output voltage.

If the input voltage makes a transition from a high level (5 V) to a low level (0 V), then the NM1 is turned off, and the NM2 is turned on. As the NM2 is turned on, the second node (B) returns to a low level, and then the PM1 is turned on. Accordingly, the first node (A) returns to a high level, and then the PM2 is turned off.

As a result, a voltage level of the second node (B) returns to a low level (0 V) since the NM2 is turned on, and this voltage (0 V) is supplied to the output voltage.

However, since the PM2 remains turned on and the NM2 makes a transition from a turned-off state to a turned on state where the input voltage makes a transition from a high level to a low level, both the PM2 and the NM2 are maintained turned on, and therefore a current flows between PM2 and NM2 during the period. On the contrary, both PM1 and NM1 are maintained turned on when the input voltage makes a transition from a low level to a high level, and therefore a current flows between PM1 and NM1. A short circuit current generated at this time disadvantageously increases power consumption of the circuit.

Also, if the input voltage makes a transition from a low level to a high level in the case of the conventional level shifter, then two phases are required for generating an output voltage, but one phase is required for generating an output voltage if the input voltage makes a transition from a high level to a low level. That is to say, a rising propagation delay and a falling propagation delay may be different in an output waveform due to the different operation phases upon generating the output voltage.

Also, the configuration of the conventional level shifter has a characteristic that its circuit operates only if the transistors NM1, NM2 to which the input voltage is applied should have a greater current driving capacity than those of the cross coupled transistors PM1, PM2, and therefore disadvantageously require a significantly large channel width.

As described above, if W (Width)/L (Length), namely a size of the transistors NM1, NM2 to which the input voltage is applied increases, then a capacitance value corresponding to the input signal is increased. Therefore its slope is reduced when the input voltage makes a transition from a low level (0 V) to a high level (5 V), or from a high level (5 V) to a low level (0 V). That is to say, since the PM1, PM2, and NM1, NM2 corresponding to the PM1, PM2 may be all turned on to generate short circuit current as described above until structurally symmetrical and opposite cross coupled transistors PM1, PM2 are turned on, the short circuit current as described above may be increased, and therefore its power consumption may be increased.

FIG. 2 is a circuit diagram showing a level shifter according to the first embodiment of the present invention. However, this is a circuit diagram of a level up shifter that takes a role in leveling up an input voltage.

A level up shifter according to an embodiment of the present invention, as shown in FIG. 2, includes a first transistor (T1) coupled with a first power supply (VDDL), and to which a gate and a drain are coupled so that they can be diode-connected. A capacitor (C) is coupled to between a first node (N1) and an input voltage terminal (IN). A second transistor (T2) is coupled to the first node (N1) to reset the capacitor (C). A third transistor (T3) has a gate coupled to the first node (N1). T3 is coupled between a second power supply (VDDH) and an output voltage terminal (OUT). A fourth transistor (T4) has a gate coupled to the first node (N1), and T3 is coupled between an inverse input voltage terminal (INb) and the output voltage terminal (OUT).

Here, the first transistor (T1) has the first power supply (VDDL) coupled to its source, and forms a diode connection structure in which the gate and the drain are coupled to each other. The drain is coupled to the first node (N1).

As shown in FIG. 2, the first transistor (T1) is a diode-connected P-channel transistor. In other embodiments the T1 may be a diode-connected N-channel transistor.

The second transistor (T2) is configured so that a reset pulse can be applied to the gate, the source can be coupled to a ground voltage (GND), and the drain can be coupled to the first node (N1).

Accordingly, the second transistor (T2) is turned on by the reset pulse applied to the gate, and therefore takes a role in resetting the capacitor (C), which is coupled to the first node (N1). It is also coupled to the ground voltage (GND) when the input voltage, which is input at the input voltage terminal (IN), is at a low level (0 V), and the inverse input voltage, which is input at the inverse input voltage terminal (INb), is at a high level (5 V) by transferring the ground voltage (GND), coupled to the source, to the first node (N1).

However, the reset pulse is applied once for the operation of the level up shifter according to an embodiment of the present invention, and therefore the capacitor is reset to a ground voltage, namely 0 V by the operation.

Also, both of the third transistor (T3) and fourth transistor (T4) are configured such that they are not turned on at the same time since they are configured as different types although the gate of each is coupled to the first node (N1). The third transistor (T3) operates as a pull up transistor and the fourth transistor (T4) operates as a pull down transistor.

In the case of the embodiment shown in FIG. 2, the third transistor (T3) consists of a P-channel transistor and the fourth transistor (T4) consists of an N-channel transistor.

Accordingly, a level shifter circuit according to one embodiment of the present invention includes one capacitor, first and second transistors for resetting the capacitor so as to charge the capacitor and preventing a reverse current that may be generated by a capacitor coupling effect and a third transistor (T3) as the pull up transistor and a fourth transistor (T4) as the pull down transistor. The third and fourth transistors (T3,T4) receive a voltage, boosted by the capacitor coupling, wherein the voltage is an input signal to the gates of T3, T4.

A source of the third transistor (T3) is coupled to a second power supply (VDDH) and a drain is coupled to the output voltage terminal (OUT). A source of the fourth transistor (T4) is coupled to an inverse input voltage terminal (INb), and a drain is coupled to the output voltage terminal (OUT).

The second power supply (VDDH) is configured such that has a voltage that is greater than a first power supply (VDDL) used for charging the capacitor (C).

In some embodiments, the second power supply (VDDH) is supplied at a level 2 times greater than the first power supply (VDDL).

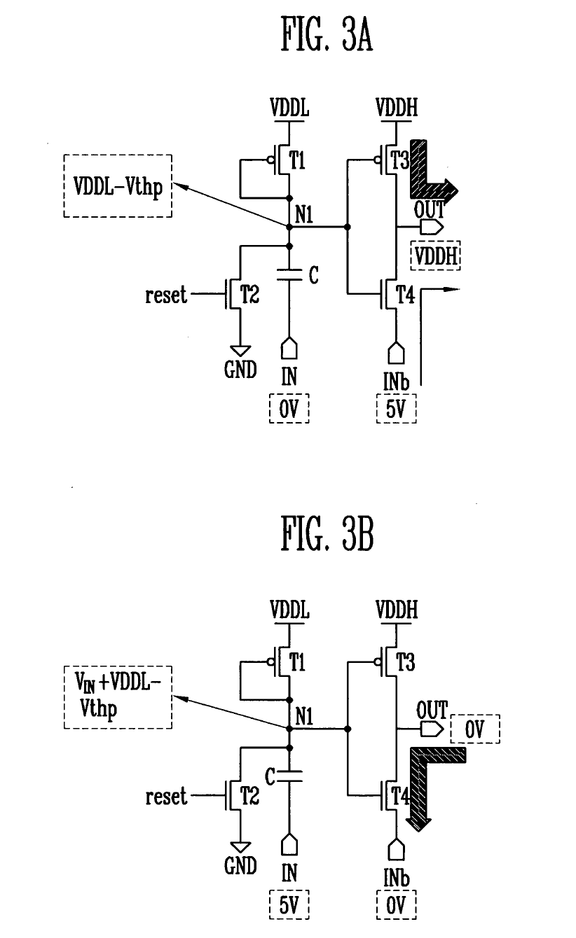

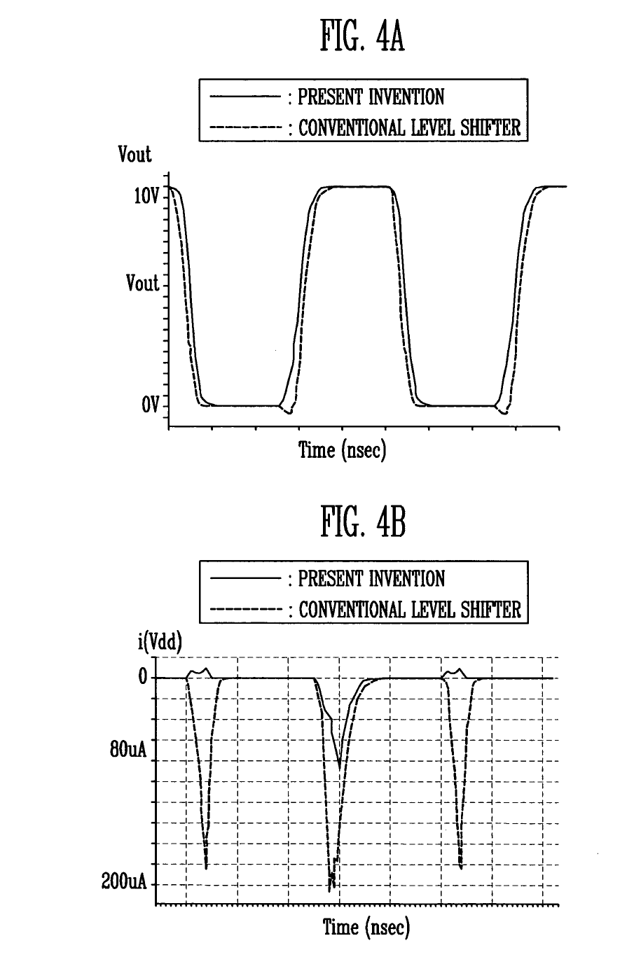

FIG. 3A and FIG. 3B are circuit diagrams illustrating an operation of the level shifter circuit as shown in FIG. 2.

Referring to FIG. 3A and FIG. 3B, an operation of the level shifter circuit according to one embodiment of the present invention, as shown in FIG. 2, will be described in detail, as follows. The description of the operation will be described for the embodiment wherein the input voltage, which is input at input voltage terminal (IN), is 0 V to 5 V, the output voltage, which is output at output voltage terminal (OUT), is 0 V to 10 V, the first power supply (VDDL) is 5 V, and the second power supply (VDDH) is 10 V.

Referring to FIG. 3A, if the input voltage is applied at a low level, namely 0 V, then the capacitor (C) is reset to a ground voltage value when a second transistor (T2) is turned on. Then, the first node (N1) returns to VDDL—Vth by the diode-connected first transistor (T1) to charge 5 V−Vth in both ends of the capacitor (C). Here, the Vth represents a threshold voltage of the first transistor (T1).

A drain of the diode-connected first transistor (T1) becomes 5 V−Vth. Therefore the 5 V−Vth is also applied to a gate coupled with the drain. Therefore, the first transistor (T1) is turned off.

Since an inverse input voltage, which is applied at inverse input voltage terminal (Inb), is applied with a high level, namely 5 V, a voltage difference between the gate and the source of the fourth transistor (T4) as the pull down transistor becomes −Vth. Therefore the fourth transistor (T4) is turned off, while the third transistor (T3) as the pull up transistor is turned on. Therefore the output voltage becomes 10 V by the second power supply (VDDH) input into the source of the third transistor (T3).

Referring to FIG. 3B, if the input voltage makes a transition from a low level (0 V) to a high level (5 V), then a voltage of the first node (N1) is boosted to V_{IN}+VDDL—Vth, namely 10 V−Vth by a capacitor coupling effect.

The first node (N1) is changed into a source in the drain of the turned-off first transistor (T1), and therefore a voltage difference between the gate and the source becomes 0 V, and the first transistor (T1) is turned off. Accordingly, the first node (N1) may be allowed to maintain the boosted voltage by suppressing a reverse current that may be generated by the capacitor coupling effect.

The inverse input voltage returns to a low level (0 V), and therefore a voltage difference between the gate and the source of fourth transistor (T4) as the pull down transistor becomes 10 V−Vth. Accordingly, the fourth transistor (T4) is turned on, while the third transistor (T3) as the pull up transistor is turned off, and therefore the output voltage becomes 0 V.

Also, when the output voltage is 0 V, the first node (N1) returns to Vth and the inverse input voltage returns to 5 V by the capacitor coupling effect if the input voltage makes a transition from a high level (5 V) to a low level (0 V). Therefore a reverse current flows toward the output voltage terminal (OUT) through the fourth transistor (T4) which is the pull down transistor, resulting in the rapid charging of the output voltage to 10 V, as shown in FIG. 3A.

Accordingly, the level shifter having the configuration relieves a difference of driving capacity by the voltage difference between the gate and the source of the third transistor (T3) as the pull up transistor and the fourth transistor (T4) as the pull down transistor by voltage boosting.

The short circuit current is very low since one of the third transistor (T3) or the fourth transistor (T4) is turned on after the input voltage makes a structural transition, and a rising propagation delay and a falling propagation delay may be set to substantially the same extent since the output voltage undergoes the same phases when its voltage is changed from 10 V to 0 V or from 0 V to 10 V.

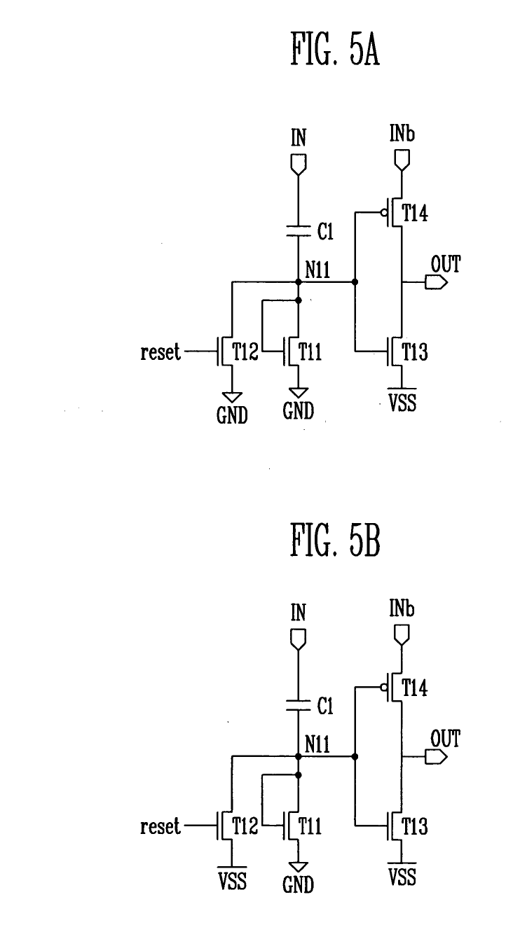

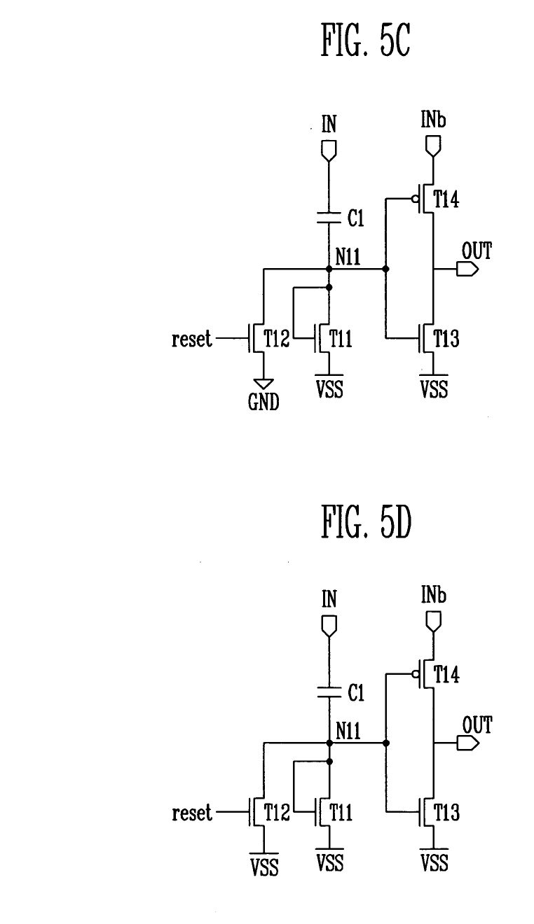

FIG. 4A is a simulation view showing an output waveform of the level shifter circuit as shown in FIG. 2; and FIG. 4B is a simulation view showing a current waveform supplied from the power source.

The output waveform of the level shifter according to one embodiment of the present invention exhibits a uniform rising propagation delay and a uniform falling propagation delay when compared to the output waveform of the conventional level shifter, and its delays are also reduced, as shown in FIG. 4A.

Referring to FIG. 4B, the output waveform of the level shifter according to one embodiment of the present invention has a low short circuit current, compared to that of the conventional level shifter.

The level shifter having the configuration relieves a difference of driving capacity by the voltage difference between the gate and the source of the third transistor (T3) as the pull up transistor and the fourth transistor (T4) as the pull down transistor by voltage boosting.

The short circuit current is very low since one of the third transistor (T3) or the fourth transistor (T4) is turned on after the input voltage makes a structural transition, and a rising propagation delay and a falling propagation delay may be set to substantially the same extent since the output voltage undergoes the same phases when its voltage is changed from 10 V to 0 V or from 0 V to 10 V.

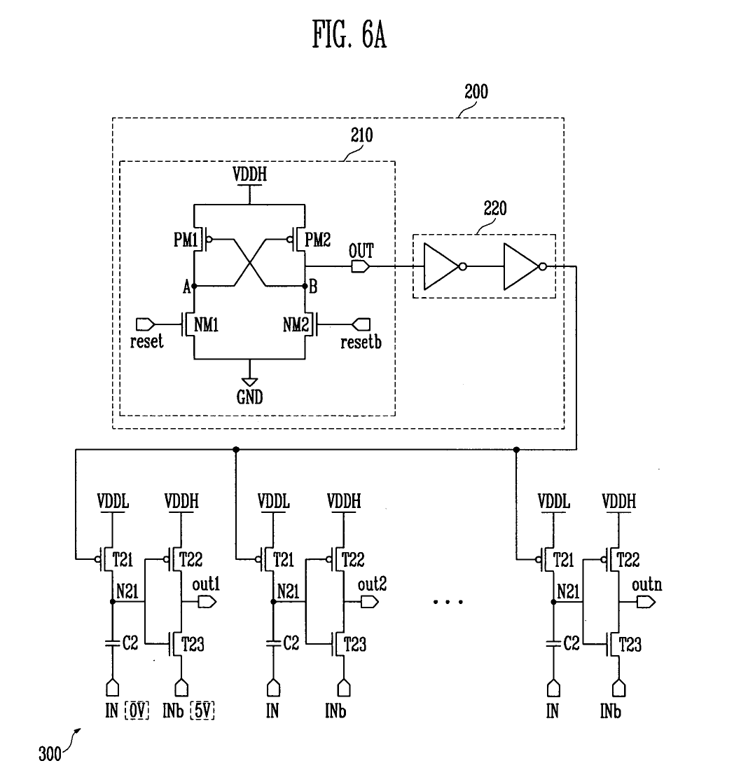

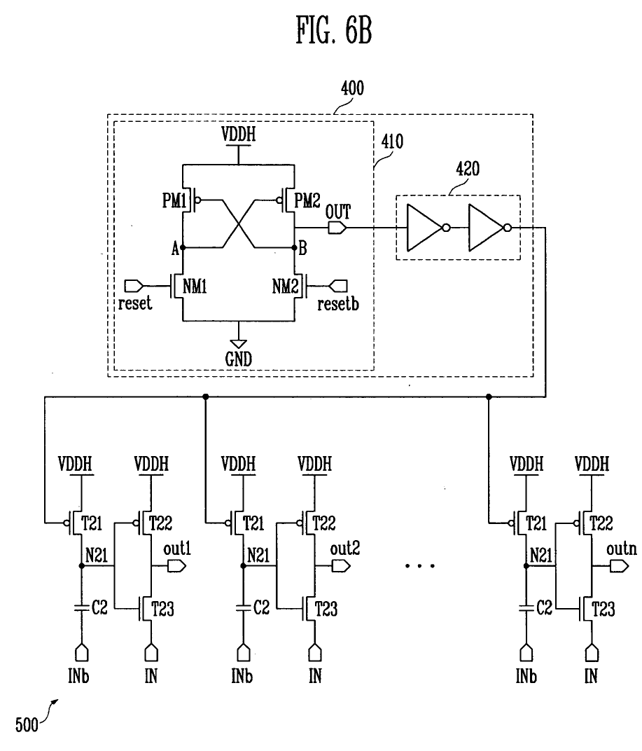

FIGS. 5A, 5B, 5C and 5D are circuit diagrams showing a level shifter according to the second embodiment of the present invention. However, these are circuit diagrams of a level down shifter, and when compared to the level up shifter as shown in FIG. 2, the level shifter of the present invention is different in an aspect of its configuration in that a direction of the diode-connected transistor is opposite and the third power supply (VSS) has a negative voltage level.

IN and INb represent an input voltage terminal, to which an input voltage is applied, and an inverse input voltage terminal, to which an inverse input voltage is applied, respectively, and OUT represents an output voltage terminal, from which an output voltage is output.

Hereinafter, the operation of the level down shifter is described for the case that the third power supply (VSS) is −5 V, and the input voltage is 0 to 5 V.

Referring to FIGS. 5A, 5B, 5C and 5D, the level down shifter according to the embodiment of the present invention includes a first transistor (T11) coupled with a ground voltage (GND) or a third power supply (VSS) and diode-connected; a capacitor (C) coupled between a first node (N11) and an input voltage terminal (IN); a second transistor (T12) coupled between the first node (N11) and the ground voltage (GND) or the third power supply (VSS) to reset the capacitor (C1); a third transistor (T13) having a gate coupled to the first node (N11), and T13 is coupled between the third power supply (VSS) and the output voltage terminal (OUT); and a fourth transistor (T14) having a gate coupled to the first node (N1), and T14 is coupled between an inverse input voltage terminal (INb) and the output voltage terminal (OUT).

The level down shifters, as shown in FIGS. 5A, 5B, 5C, and 5D, are different embodiments depending on whether or not the ground voltage (GND) or the third power supply (VSS) is coupled to sources of the first transistor (T11) and the second transistor (T12), and whether the input voltage is input at an initial low level or an initial high level.

Here, the first transistor (T11) is coupled with the ground voltage (GND) or the third power supply (VSS) through the source, and has a diode connection structure in which the gate and the drain are coupled to each other, and the drain is coupled to the first node (N11).

As shown in FIGS. 5A, 5B, 5C and 5D, the first transistor (T11) includes diode-connected N-channel transistors, but this is one embodiment and the T11 may include diode-connected P-channel transistors in other embodiments.

Also, the second transistor (T12) is configured so that a reset pulse can be applied to the gate, the source can be coupled to a ground voltage (GND) or a third power supply (VSS), and the drain can be coupled to the first node (N11).

Accordingly, the second transistor (T12) is turned on by the reset pulse applied to the gate, and therefore takes a role in resetting the capacitor (C1), coupled to the first node (N11), to the ground voltage (GND) by transferring the ground voltage (GND) or the third power supply (VSS), coupled to the source, to the first node (N11).

However, the reset pulse is applied once for the operation of the level up shifter according to an embodiment of the present invention, and therefore the capacitor is reset to a ground voltage or third power supply (VSS) by the operation.

Also, both of the third transistor (T13) and fourth transistor (T14) are characterized in that they are not turned on at the same time since they are configured as different types of transistors although the gate for each is coupled to the first node (N11).

In the case of the embodiment as shown in FIGS. 5A, 5B, 5C and 5D, the third transistor (T13) includes N-channel transistors, and the fourth transistor (T14) includes P-channel transistors.

Accordingly, a level down shifter circuit according to each embodiment of the present invention includes one capacitor; first and second transistors for initially resetting the capacitor so as to charge the capacitor and prevent a reverse current that may be generated by a capacitor coupling effect; and a third transistor (T13) as the pull up transistor and a fourth transistor (T14) as the pull down transistor. The third and fourth transistors (T13,T14) receive a voltage, boosted by the capacitor coupling, wherein the voltage is an input voltage input into the gate of T13 and the gate of T14.

A source of the third transistor (T13) is coupled to a third power supply (VSS), which is the supply power, and a drain is coupled the output voltage terminal (OUT). A source of the fourth transistor (T14) is coupled to an inverse input voltage terminal (INb), and a drain is coupled to the output voltage terminal (OUT).

Detailed description of an operation of the level down shifter having such a configuration is omitted since the level down shifter is operated according to the same principle as the level up shifter as shown above in FIGS. 2, 3 and 4. An operation of each embodiment as shown in FIGS. 5A, 5B, 5C and 5D will be described in brief, as follows.

First, in the case of the embodiment shown in FIG. 5A, a ground voltage (GND) is applied to sources of a first transistor (T11) and a second transistor (T12), respectively, and the input voltage is input with an initial high level, namely 5 V.

In this case, if the input voltage is input with a high level as the first node is reset to 0 V, then the level down shifter is output with the third power supply (VSS), namely −5 V due to the turn on of the third transistor (T13).

On the contrary, if the input voltage makes a transition from a high level to a low level, then the first node (N11) returns to −5 V, and therefore the level down shifter is output with 5 V, which is the inverse input voltage, since the fourth transistor (T14) is turned on.

Subsequently, in the case of the embodiment as shown in FIG. 5B, the ground voltage (GND) and the third power supply (VSS) are applied to sources of the first transistor (T11) and the second transistor (T12), respectively, and the input voltage is input with an initial low level, namely 0 V.

In this case, if the input voltage is input with a low level as the first (N11) is reset to −5 V, then the level down shifter is output with −5 V, which is the inverse input voltage, due to the fourth transistor (T14) being turned on.

On the contrary, if the input voltage makes a transition from a low level to a high level, then the first node returns to 0 V. Therefore the level down shifter is output with the third power supply (VSS), namely −5 V, since the third transistor (T13) is turned on.

Subsequently, in the case of the embodiment as shown in FIG. 5C, the third power supply (VSS) and the ground voltage (GND) are applied to sources of the first transistor (T11) and the second transistor (T12), respectively, and the input voltage is input with an initial low level, namely 0 V.

In this case, if the input voltage is input with a low level as the first node (N11) is reset to −5 V+Vth (a threshold voltage of the T11), then the level down shifter is output with 5 V, which is the inverse input voltage, due to the fourth transistor (T14) being turned on.

On the contrary, if the input voltage makes a transition from a low level to a high level, then the first node returns to 0 V+Vth (a threshold voltage of the T11), and therefore the level down shifter is output with the third power supply (VSS), namely −5 V since the third transistor (T13) is turned on.

Finally, in the case of the embodiment shown in FIG. 5D, the third power supply (VSS) is applied to sources of the first transistor (T11) and the second transistor (T12), respectively, and the input voltage is input with an initial low level, namely 0 V.

In this case, if the input voltage is input with a low level as the first node is reset to −5 V, then the level down shifter is output with 5 V, which is the inverse input voltage, due to the turn on of the fourth transistor (T14).

On the contrary, if the input voltage makes a transition from a low level to a high level, then the first node returns to 0 V. Therefore the level down shifter is output with the third power supply (VSS), namely −5 V since the third transistor (T13) is turned on.

FIG. 6A and FIG. 6B are circuit diagrams showing a level shifter according to the third embodiment of the present invention. This is a level up shifter for leveling up an input voltage, as described in the first embodiment shown above in FIG. 2.

However, the first power supply (VDDL) and the second power supply (VDDH) represent supply voltages of the level shifter; IN and INb represent an input voltage terminal of the level shifter, wherein the IN receives an input voltage, and an inverse input voltage terminal of the level shifter, wherein the INb receives an inverse input voltage, respectively. Further, out 1 to out n represent output voltage terminals that output output voltages. VDDL, VDDH, IN, INb and out 1 to out n are shown in FIG. 6A and FIG. 6B.

The second power supply (VDDH) is a positive voltage greater than that of the first power supply (VDDL), and preferably has a voltage value 2 times greater than that of the first power supply (VDDL).

In the case of the embodiment of the present invention, the case wherein the second power supply (VDDH) is applied with 10 V and the first power supply (VDDL) is applied with 5 V will be described.

First, the level shifter according to the embodiment of the present invention includes an initial charging part 200 and an n number of level shifter parts 300 individually coupled with the initial charging part 200, as shown in FIG. 6A.

Accordingly, the n number of the level shifter parts 300 is provided in order to supply the level-shifted voltage for the input voltage to each channel, and one initial charging part 200 is coupled to each of the level shifter parts 300 in order to initially charge the capacitor (C2) provided in each of the n number of the level shifter parts 300.

For this purpose, the initial charging part 200 resets the charging of the capacitor provided in each level shifter part, and each of the level shifter parts 300 realizes a low power-consumption circuit by reducing a short circuit current by a voltage boosting operation using a capacitor coupling effect, and takes a role in uniformly maintaining a rising propagation delay and a falling propagation delay of the output waveform.

First the initial charging part 200 includes a level-up circuit part 210 for receiving a reset signal (reset) and an inverse reset signal (resetb) to level up them to a predetermined voltage and output the reset signal (reset) and the inverse reset signal (resetb). The initial charging part 200 also includes a buffer part 220 for stabilizing an output voltage of the level-up circuit part 210.

The level-up circuit part 210 may have the same structure as the conventional level shifter as shown above in FIG. 1, and therefore the level-up circuit part as shown in FIG. 6 may include first and second N-channel transistors (NM1, NM2) for receiving a reset signal (reset) and an inverse reset signal (resetb); and a latch circuit for leveling up the input voltage. The latch circuit may include the first and second P-channel transistors (PM1, PM2).

In the transistors NM1, NM2, a gate is coupled with the reset signal (reset) and the inverse reset signal (resetb), respectively. A source is coupled with a ground voltage (GND), and a drain is coupled with first and second nodes (A, B), respectively, thereby being coupled to the latch circuit. The second node (B) is coupled with an output voltage terminal (OUT).

The gate and drain of the PM1, PM2, which make up the latch circuit, are cross-linked to be coupled between the first and second nodes, respectively, and the source is coupled to a supply voltage VDDH of the level-up circuit part 210.

In the case of the level-up circuit part 210 having, for example, a reset signal that ranges from 0 V to 5 V, and an output voltage that ranges from 0 V to 10 V, then an inverse reset signal (resetb) is at a low level, namely 0 V when the reset signal (reset) is at a high level, namely 5 V, and the inverse reset signal (resetb) is at a high level (5 V) when the reset signal (reset) is at a low level (0 V).

If the reset is 5 V, then NM1 to which the reset is applied is turned on, and NM2 to which the resetb is applied is turned off. Accordingly, PM2 is turned on by the turned-on NM1, and an output voltage is leveled up to 10 V by the supply voltage VDDH.

If the reset is 0 V, then NM2, to which the resetb is applied is turned on, and NM1, to which the reset is applied, is turned off. Therefore the output voltage returns to 0 V.

As described above, the output voltage of the level-up circuit part 210 is supplied to the n number of level shifter parts through the buffer part 220, respectively. In this embodiment, the buffer part may, for example, have a structure in which two inverters are coupled in series, as shown in FIG. 2A.

Also, the level shifter part 300 includes a first transistor (T21) in which the signal output from each of the initial charging parts is applied to the gate; a capacitor (C2) coupled between the first node (N21) and the input voltage terminal (IN); a second transistor (T21) in which the gate is coupled to the first node (N21), and T22 is coupled between the second power supply (VDDH) and the output voltage terminal (OUT); and a third transistor (T23) in which a gate is coupled to the first node (N21), and T23 is coupled between the inverse input voltage terminal (INb) and the output voltage terminal (OUT).

In this embodiment, a source of the first transistor (T21) is coupled with the first power supply (VDDL), and a drain is coupled to the first node (N21).

The level shifter according the embodiment of the present invention, as shown in FIG. 6B, includes an initial charging part 400 and an n number of level shifter parts 500 individually coupled with the initial charging part 400. The n number of the level shifter parts 500 is provided in order to supply the level-shifted voltage for the input voltage to each channel, and the initial charging part 400 is coupled to each of the level shifter parts 500 in order to initially charge the capacitor (C2) provided in each of the n number of the level shifter parts 500. Accordingly, the operation of the initial charging part 400 may be identical to the embodiment as shown above in FIG. 6A.

Unlike the embodiment as shown in FIG. 6A, the level shifter part 500 is characterized in that the level shifter part 500 includes a first transistor (T21) in which the signal output from each of the initial charging parts 400 is applied to the gate; a capacitor (C) coupled between the first node (N21) and the inverse input voltage terminal (INb); a second transistor (T22) in which the gate is coupled to the first node (N21), and T22 is coupled between the second power supply (VDDH) and the output voltage terminal (OUT); and a third transistor (T23) in which the gate is coupled to the first node (N21), and T23 is coupled between the input voltage terminal (IN) and the output voltage terminal (OUT).

Accordingly, when compared to the embodiment as shown in FIG. 6A, there is a difference in that the first power supply (VDDL) is removed, and the input voltage and the inverse input voltage are input in reverse order.

Accordingly, a source of the first transistor (T21) is coupled with the first power supply (VDDL) in the case of the embodiment as shown in FIG. 6A, and coupled with the second power supply (VDDH) in the case of the embodiment shown in FIG. 6B, and a drain is coupled to the first node (N21).

Also, both of the second transistor (T22) and the third transistor (T23) are characterized in that they are not turned on at the same time since they are configured as different types of transistors although both of their gates are coupled to the first node (N21).

Accordingly, the second transistor (T22) operates as a pull up transistor, and the third transistor (T23) operates as a pull down transistor.

In the case of the embodiments shown in FIG. 6A and FIG. 6B, the second transistor (T22) is a P-channel type transistor, and the third transistor (T23) is an N-channel type transistor.

Accordingly, the level shifter part includes one capacitor; a first transistor (T21) for initially resetting the capacitor so as to charge the capacitor and prevent a reverse current that may be generated by a capacitor coupling effect; a second transistor (T22) as the pull up transistor; and a third transistor (T23) as the pull down transistor. The third transistor (T23) receives a voltage, boosted by the capacitor coupling, wherein the voltage is an input voltage received in the gate of (T23).

Accordingly, a source of the second transistor (T22) is coupled to a second power supply (VDDH), which is the supply power, and a drain is coupled to the output voltage terminals (out 1 to out n); and a source of the third transistor (T23) is coupled to an inverse input voltage terminal (INb), and a drain is coupled to the output voltage terminals (out 1 to out n).

Also, the second power supply (VDDH)is characterized in that it has a voltage greater than the first power supply (VDDL) used for charging the capacitor (C2), and may have a positive voltage value 2 times greater than the first power supply (VDDL).

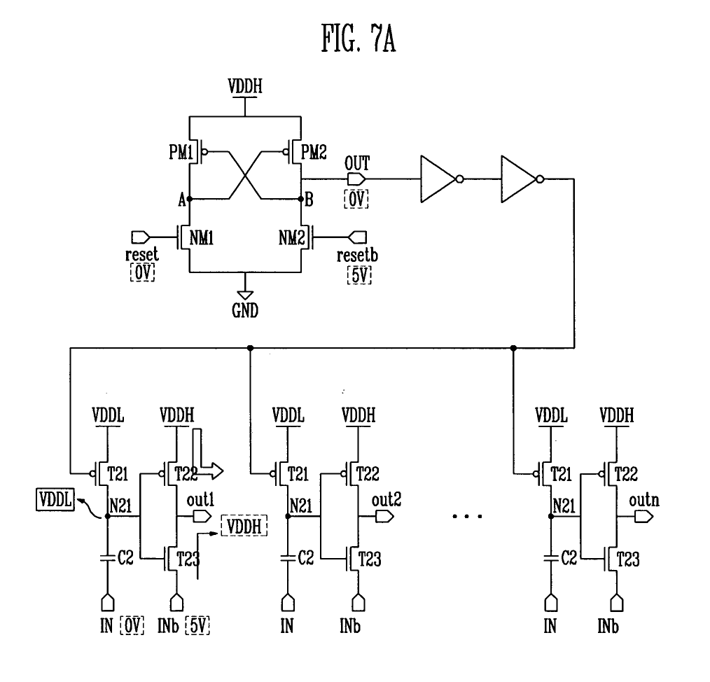

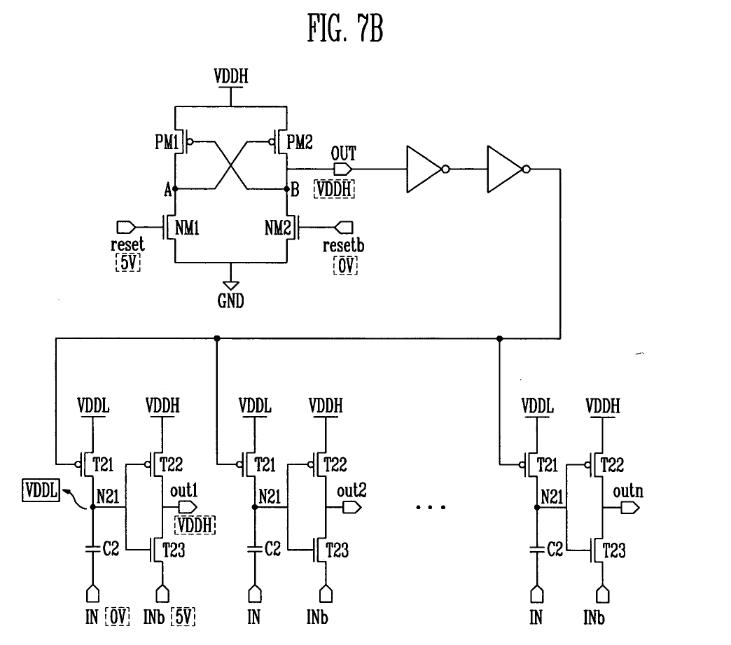

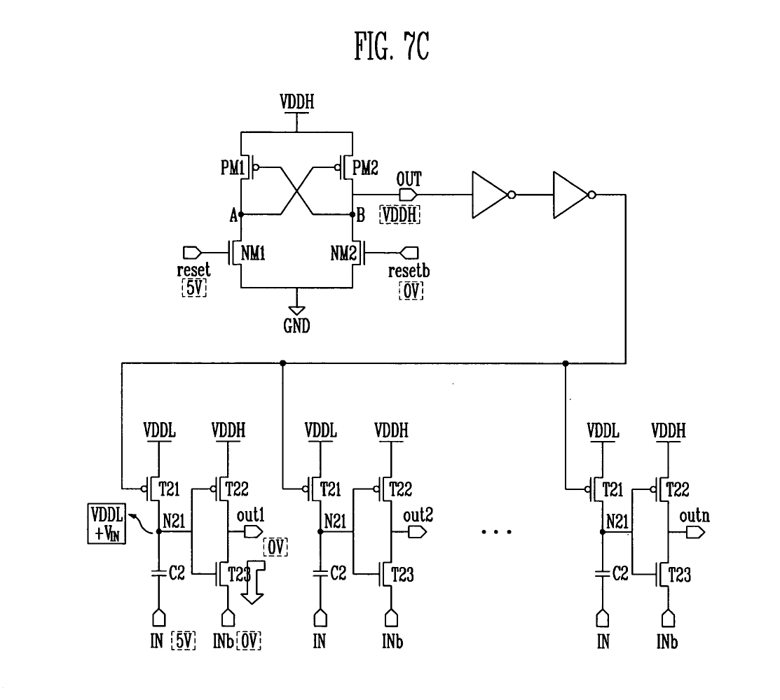

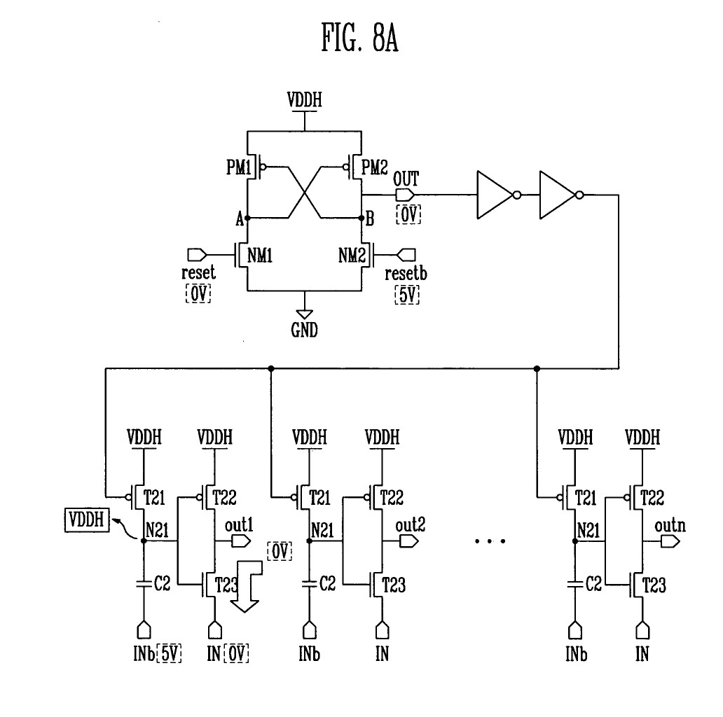

FIGS. 7A, 7B and 7C are diagrams illustrating an operation of the level shifter circuit as shown in FIG. 6A. Referring to FIGS. 7A, 7B and 7C, an operation of the level shifter circuit according to the embodiment of the present invention, as shown in FIG. 6A, will be described in detail.

The case wherein the input voltage is 0 V to 5V, the output voltage is 0 V to 10 V, the first power supply (VDDL) is 5 V, the second power supply (VDDH) is 10 V, and the reset signal (reset) is 0 V to 5 V will be described.

First, referring to FIG. 7A, if the input voltage, which is input at input voltage terminal (IN), is applied with an initial low level, namely 0 V, then the reset signal (reset) of the level-up circuit part provided in the initial charging part is also supplied with a low level (0 V).

As a result, the initial charging part outputs the low level, namely 0 V, and then supplies the low level to the gate of the first transistor (T21), provided in the level shifter part, through the buffer part. The first transistor (T21) is turned on by the signal since the first transistor (T21) is the P-channel transistor.

Accordingly, a voltage of 5 V is applied to the first node (N21), and the capacitor (C2) is initially charged with a voltage of 5 V.

A voltage difference between the gate and the source of the third transistor (T23) as the pull down transistor becomes 0 V since the inverse input voltage is applied with a high level, namely 5 V. Therefore the third transistor (T23) is turned off, while the second transistor (T22) as the pull up transistor is turned on. Then the output voltages that are output to output voltage terminals (out 1 to out n), respectively, return to 10 V by the second power supply (VDDH) input into a source of the second transistor (T22).

Also, the reset signal (reset) of the level-up circuit part provided in the initial charging part as shown in FIG. 7B is changed to a high level (5 V) and supplied after a voltage of 5 V is applied to the first node (N21) and the capacitor (C2) is charged with a voltage of 5 V. Therefore the initial charging part outputs 10 V as the high level, namely VDDH to supply the voltage of 10 V to the gate of the first transistor (T21) provided in the level shifter part, and then the first transistor (T21) is turned off.

As the first transistor (T21) is turned off, the first node is at a floating state, the capacitor (C2) is maintained with the initially charged 5 V, and the output voltages that are output voltage terminals (out 1 to out n) are also maintained at 10 V, as shown above in FIG. 7A.

That is to say, according to the present invention, the capacitor may not be affected by a threshold voltage of the first transistor (T21), and a difference between the first power supply (VDDL) and the input voltage may be maintained intact.

Here, when the input voltage is input with an initial low level, the reset signal (reset) is changed from a low level (0 V) to a high level (5 V), and then supplied to the level-up circuit part provided in the reset charging part as shown in FIG. 7A and FIG. 7B, and therefore the first transistor (T21) is turned off, and then the initially charged 5 V is maintained in the capacitor (C2) by maintaining the first node(N21) at a floating state.

Also, referring to FIG. 7C, if the input signal (IN) is changed from a low level (0 V) to a high level (5 V), then a voltage of the first node (N21) is boosted to IN+VDDL, namely 10 V by a capacitor coupling effect.

The first transistor (T21) is maintained turned-off, and therefore the voltage of the first node (N21) may be maintained with 10 V since the reverse current, which may be generated by the capacitor coupling effect, is suppressed.

The inverse input voltage returns to a low level (0 V), and then a voltage difference between the gate and the source of the third transistor (T23) as the pull down transistor becomes 10 V. Accordingly, the third transistor (T23) is turned on, while the output voltages output to output voltage terminals (out 1 to out n) become 0 V since the second transistor (T22) as the pull up transistor is turned off.

Also, when the output voltages output to output voltage terminals (out 1 to out n) are at 0 V, the first node (N21) becomes 5 V by means of the capacitor coupling effect if the input signal (IN) makes a transition from a high level (5 V) to a low level (0 V), and the inverse input voltage also becomes 5 V. Therefore a reverse current flows toward the output voltage (out 1 to out n) terminals through the third transistor (T23) as the pull down transistor, and then the output voltages (out 1 to out n) are rapidly charged with 10 V, as shown in FIG. 7A.

The level shifter part having the configuration relieves a difference of a driving capacity by the voltage difference between the gate and the source of the second transistor (T22) and the third transistor (T23) by voltage boosting.

Also, the short circuit current may be very low since one of the second transistor (T22) the pull up transistor and the third transistor (T23) as the pull down transistor is turned on after the input voltage makes a structural transition. Additionally a rising propagation delay and a falling propagation delay may be set to the identical extent since the output voltage output to output voltage terminals (out 1 to out n) undergo the same phases when its voltage is changed from 10 V to 0 V or from 0 V to 10 V

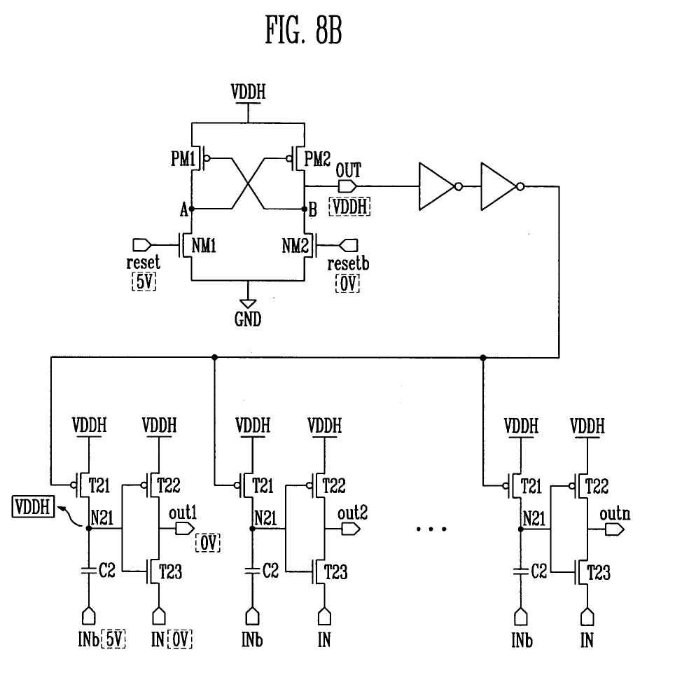

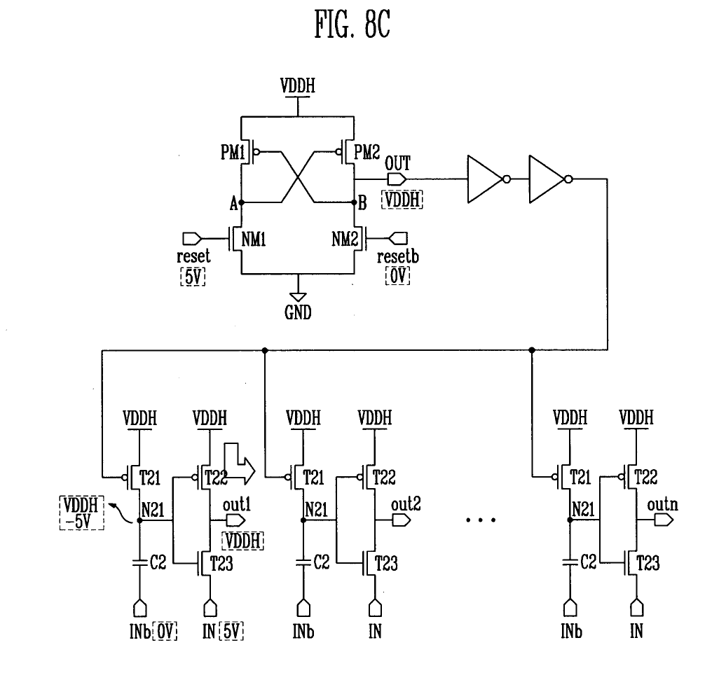

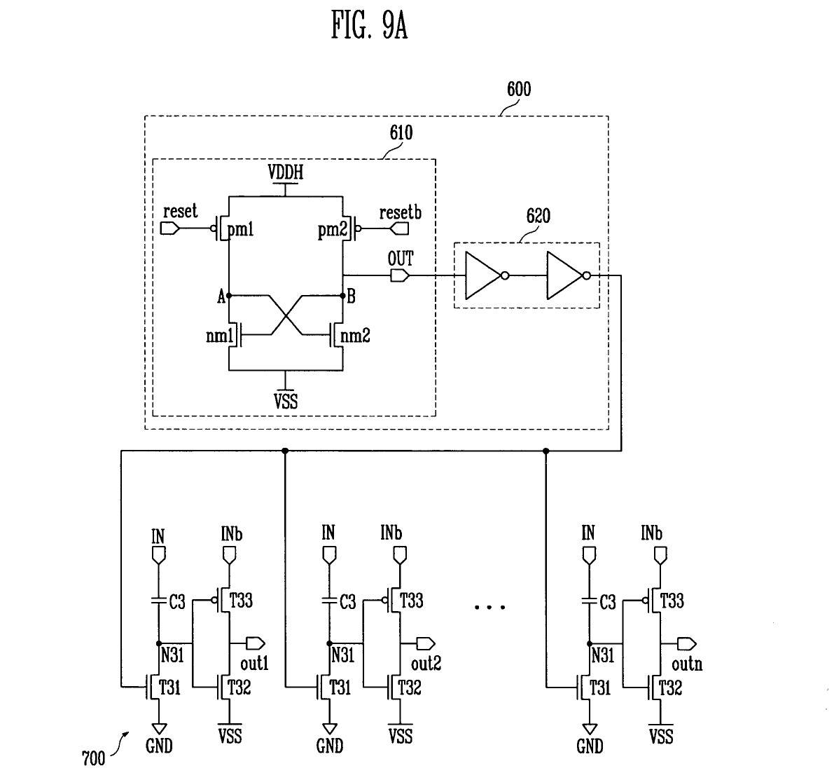

Next, FIGS. 8A, 8B and 8C are diagrams illustrating an operation of the level shifter circuit as shown in FIG. 6B. Referring to FIGS. 8A, 8B and 8C, an operation of the level shifter circuit according to the embodiment of the present invention, as shown in FIG. 6B, will be described in detail, as follows.

The case when the input voltage is 0 V to 5 V, the output voltage is 0 V to 10 V, the second power supply (VDDH) is 10 V, and the reset signal (reset) is 0 V to 5 V will be described.

When compared to the embodiment as shown above in FIG. 8A, it is characterized in that the first power supply (VDDL) is not supplied, and therefore the second power supply (VDDH) may be freely supplied.

First, referring to FIG. 8A, the input voltage, which is input at input voltage terminal (IN), is applied with an initial low level, namely 0 V. Therefore the reset signal (reset) of the level-up circuit part provided in the initial charging part is also supplied with the low level (0 V) if the inverse input signal is applied with an initial high level, namely 5 V.

As a result, the initial charging part outputs the low level, namely 0 V, and then supplies the low level to the gate of the first transistor (T21) provided in the level shifter part. The first transistor (T21) is turned on by the signal since the first transistor (T21) is the P-channel transistor.

Accordingly, both ends of the capacitor (C2) are charged with VDDH-5 V, namely 5 V since the first node (N21) becomes VDDH, namely 10 V by the first transistor (T21). The capacitor (C2) is provided between the first node and the inverse input voltage terminal (INb).

A voltage difference between the gate and the source of the third transistor (T23) as the pull down transistor becomes 10 V since the input voltage is applied with a low level, namely 0 V. Therefore the third transistor (T23) is turned on, while the output voltages output to output voltage terminals (out 1 to out n) become 0 V since the second transistor (T22) as the pull up transistor is turned off.

Also, the reset signal (reset) of the level-up circuit part provided in the initial charging part as shown in FIG. 8B is changed into a high level (5 V) and supplied after a voltage of 5 V is applied to the first node (N21) and the capacitor (C2) is charged with a voltage of 5 V. Therefore the initial charging part outputs 10 V such as the high level, namely VDDH to supply the voltage of 10 V to the gate of the first transistor (T21) provided in the level shifter part. Then the first transistor (T21) is turned off.

As the first transistor (T21) is turned off, the first node is at a floating state, the capacitor (C2) is maintained with the initially charged 5 V, and the output voltages output to output voltage terminals (out 1 to out n) are also maintained with 10 V, as shown above in FIG. 8A.

According to the present invention, the capacitor is not affected by a threshold voltage of the first transistor (T21), and a difference between the first power supply (VDDL) and the input voltage may be maintained intact.

In this embodiment, when the input voltage is input at an initial low level, the reset signal (reset) is changed from a low level (0 V) to a high level (5 V), and then supplied to the level-up circuit part provided in the reset charging part as shown in FIG. 8A and FIG. 8B. Therefore the first transistor (T21) is turned off, and then the initially charged 5 V is maintained in the capacitor (C2) by maintaining the first node at a floating state.

Also, referring to FIG. 8C, if the input voltage is changed from a low level (0 V) to a high level (5 V), namely the inverse input voltage is changed from a high level (5 V) to a low level (0 V) and input, then a voltage of the first node (N21) is changed into VDDH-5 V, namely 5 V so as to maintain the voltage value stored in the capacitor by the capacitor coupling effect.

The first transistor (T21) is maintained turned-off, and therefore the voltage of the first node (N21) may be maintained with 5 V since the reverse current which may be generated by the capacitor coupling effect is suppressed.

The input voltage returns to a high level (5 V), and then a voltage difference between the gate and the source of the third transistor (T23) as the pull down transistor becomes 0 V. Accordingly, the third transistor (T23) is turned off, while the output voltages output to output voltage terminals (out 1 to out n) become 10 V by the second power supply (VDDH) input into the source of the second transistor (T22) since the second transistor (T22) as the pull up transistor is turned on.

The level shifter part having the configuration relieves a difference of a driving capacity by the voltage difference between the gate and the source of the second transistor (T22) as the pull up transistor and the third transistor (T23) as the pull down transistor by the voltage boosting.

Also, the short circuit current may be very low since one of the second transistor (T22) as the pull up transistor and the third transistor (T23) as the pull down transistor is turned on after the input voltage makes a structural transition. Additionally, a rising propagation delay and a falling propagation delay may be set to the identical extent since the output voltages output to output voltage terminals (out 1 to out n) undergo the same phases when the output voltages are changed from 10 V to 0 V or from 0 V to 10 V.

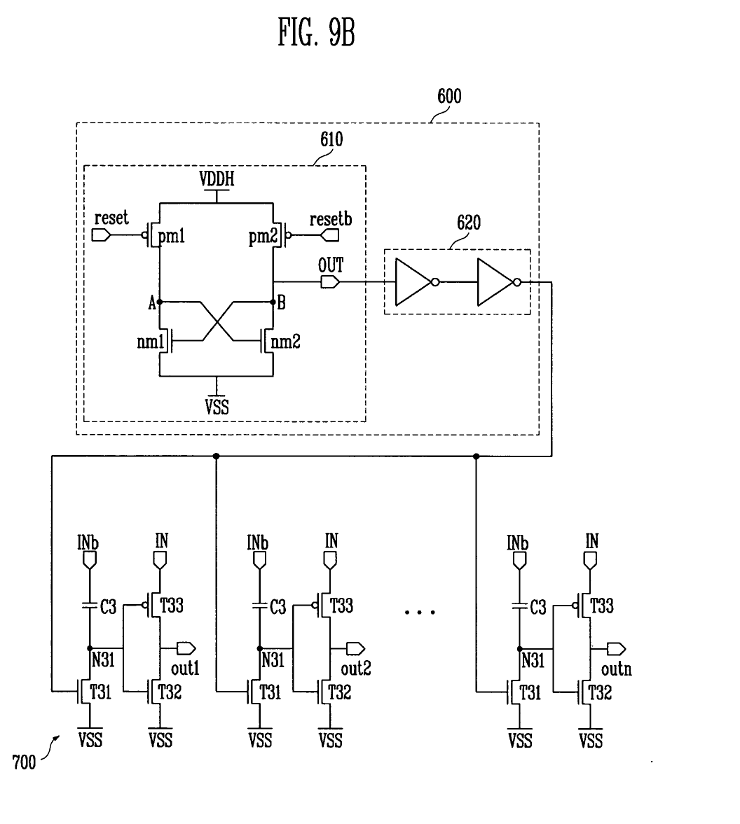

FIG. 9A and FIG. 9B are circuit diagrams showing a level shifter according to the fourth embodiment of the present invention. However, these are circuit diagrams of a level down shifter, and when compared to the level up shifter as shown in FIG. 6, the level shifter of the present invention is different in an aspect of its configuration in that the third power supply (VSS) has a negative voltage level.

The third power supply (VSS) represents a supply voltage of the level down shifter, the IN and INb represent an input voltage terminal that receives an input voltage of the level down shifter and an inverse input voltage terminal that receives an inverse input voltage of the level down shifter, respectively, and the OUT represents an output voltage terminal that outputs an output voltage.

Referring to FIG. 9A and FIG. 9B, the level down shifter according to the embodiment of the present invention includes an initial charging part 600 and the n number of level shifter parts 700 individually coupled with the initial charging part 600.

First, the initial charging part 600 includes a level down circuit part 610 for receiving a reset signal (reset) and an inverse reset signal (resetb) to level down them to a predetermined voltage and outputting the reset signal (reset) and the inverse reset signal (resetb). The initial charging part 600 also includes a buffer part 620 for stabilizing an output voltage of the level down circuit part 610.

The level down circuit part 610 includes first and second P-channel transistors (pm1, pm2) for receiving a reset signal (reset) and an inverse reset signal (resetb); and a latch circuit for leveling down the input voltage. The latch circuit includes first and second N-channel transistors (nm1, nm2).

In the transistors (pm1, pm2), a gate is coupled with the reset signal (reset) and the inverse reset signal (resetb); a source is coupled with a first voltage (VDDH), and a drain is contacted with first and second nodes (A, B), thereby being coupled to the latch circuit. However, the second node (B) is coupled with an output voltage terminal (OUT).

The gate and the drain of nm1, nm2 that make up the latch circuit, are cross-linked to be coupled between the first and second nodes, respectively, and the source is coupled to a supply voltage, the third power supply (VSS), of the level down circuit part.

In the case of the level down circuit part having the configuration, for example, an input voltage has a range of 0 V to 5 V, and an output voltage has a range of 0 V to 10 V.

As described above, an output voltage of the level down circuit part is supplied to the n number of level shifter parts through the buffer part 620, respectively. In this embodiment, the buffer part may, for example, have a structure in which two inverters are coupled in series, as shown in FIG. 5.

Also, the level shifter part 700 includes a first transistor (T31) in which the signal output from each of the initial charging parts is applied to the gate of (T31), and T31 is provided between the first node (N31) and the ground voltage (GND) or the third power supply (VSS); a capacitor (C3) coupled between the first node (N31) and the input voltage terminal (IN) or the inverse input voltage terminal (INb); a second transistor (T32) in which the gate is coupled to the first node (N31), and (T32) is coupled between the third power supply (VSS) and the output voltage terminal (OUT); and a third transistor (T33) in which the gate is coupled to the first node (N31), and (T33) is coupled between the inverse input voltage terminal (INb) or the input voltage terminal (IN) and the output voltage terminal (OUT).

In the case of the embodiment as shown in FIG. 9A, the level shifter part 700 includes a first transistor (T31) in which the signal output from each of the initial charging parts is applied to the gate, and provided between the first node (N31) and the ground voltage (GND); a capacitor (C3) coupled between the first node (N31) and the input voltage terminal (IN); a second transistor (T32) in which the gate is coupled to the first node (N31), and (T32) is coupled between the third power supply (VSS) and the output voltage terminal (OUT); and a third transistor (T33) in which the gate is coupled to the first node (N31), and (T33) is coupled between the inverse input voltage terminal (INb) and the output voltage terminal (OUT).

In the case of the embodiment as shown in FIG. 9B, the level shifter part 700 includes a first transistor (T31) in which the signal output from each of the initial charging parts is applied to the gate, and provided between the first node (N31) and the third power supply (VSS); a capacitor (C3) coupled between the first node (N31) and the inverse input voltage terminal (INb); a second transistor (T32) in which the gate is coupled to the first node (N31), and (T32) is coupled between the third power supply (VSS) and the output voltage terminal (OUT); and a third transistor (T33) in which the gate is coupled to the first node (N31), and (T33) is coupled between the input voltage terminal (IN) and the output voltage terminal (OUT).

The level down shifter having such a configuration is operated according to the same operation principle as the level up shifter as described above with reference to FIGS. 6, 7 and 8, and therefore its detailed description is omitted.

As described above, the level shifter part of the present invention may realize a low power-consumption circuit by reducing a short circuit current by a voltage boosting operation using a capacitor coupling effect and uniformly maintains a rising propagation delay and a falling propagation delay of an output waveform.

Although exemplary embodiments of the present invention have been shown and described, it would be appreciated by those skilled in the art that changes might be made in this embodiment without departing from the principles and spirit of the invention, the scope of which is defined in the claims and their equivalents.

What is claimed is:

1. A level shifter for a flat panel display device, the level shifter comprising:
a first transistor coupled with a first power supply, the first transistor having a gate and a drain that are coupled together;
a capacitor coupled between an input voltage terminal and a first node coupled with the drain of the first transistor;
a second transistor coupled with the first node and adapted to reset the capacitor;
a third transistor having a gate coupled to the first node, wherein the third transistor is coupled between a second power supply and an output voltage terminal; and
a fourth transistor having a gate coupled to the first node, wherein the fourth transistor is coupled between an inverse input voltage terminal and the output voltage terminal.

2. The level shifter for a flat panel display device according to claim 1, wherein the first transistor is a diode-connected P-channel transistor or an N-channel transistor.

3. The level shifter for a flat panel display device according to claim 1, wherein the second transistor comprises:
a gate adapted to receive a reset pulse;
a source coupled to a ground; and
a drain coupled to the first node.

4. The level shifter for a flat panel display device according to claim 1, wherein the third transistor and the fourth transistor are different types of transistors.

5. The level shifter for a flat panel display device according to claim 4, wherein:
a source of the third transistor is coupled to the second power supply;
a source of the fourth transistor is coupled to the inverse input voltage terminal; and
a drain of the third transistor and a drain of the fourth transistor are coupled to the output voltage terminal.

6. The level shifter for a flat panel display device according to claim 1, wherein the second power supply has a voltage value that is about twice that of the first power supply.

7. A level shifter for a flat panel display device, the level shifter comprising:
a first transistor coupled with a ground voltage or a power supply, and having a gate and a drain coupled together;
a capacitor coupled between an input voltage terminal and a first node coupled with the drain of the first transistor;
a second transistor coupled between the first node and the ground voltage or the power supply to reset the capacitor;
a third transistor having a gate coupled to the first node, wherein the third transistor is coupled between the power supply and an output voltage terminal; and
a fourth transistor having a gate coupled to the first node, wherein the fourth transistor is coupled between an inverse input voltage terminal and the output voltage terminal.

8. The level shifter for a flat panel display device according to claim 7, wherein the first transistor is a diode-connected N-channel transistor or a P-channel transistor.

9. The level shifter for a flat panel display device according to claim 7, wherein the second transistor comprises:
a gate adapted to receive a reset pulse;
a source coupled with the ground voltage or the power supply; and
a drain coupled to the first node.

10. The level shifter for a flat panel display device according to claim 7, wherein the third transistor and the fourth transistor are different types of transistors.

11. The level shifter for a flat panel display device according to claim 10, wherein:
a source of the third transistor is coupled to the power supply;
a source of the fourth transistor is coupled to the inverse input voltage terminal; and
a drain of the third transistor and a drain of the fourth transistor are coupled to the output voltage terminal.

12. The level shifter for a flat panel display device according to claim 7, wherein the power supply has a negative voltage value.

13. A level shifter for a flat panel display device, the level shifter comprising:
an initial charging part; and
a plurality of level shifter parts individually coupled with the initial charging part,
wherein each of the plurality of level shifter parts comprises:
a first transistor having a gate adapted to receive a signal output from the initial charging part;
a capacitor coupled between an input voltage and a first node to which a drain of the first transistor is coupled;
a second transistor having a gate coupled to the first node, wherein the second transistor is coupled between a first power supply and an output voltage terminal; and
a third transistor having a gate coupled to the first node, wherein the third transistor is coupled between an inverse input voltage terminal and the output voltage terminal.

14. The level shifter for a flat panel display device according to claim 13, wherein a source of the first transistor is coupled to a second power supply.

15. The level shifter for a flat panel display device according to claim 13, wherein the second power supply outputs a positive voltage lower than that of the first power supply.

16. The level shifter for a flat panel display device according to claim 13, wherein the second transistor and the fourth transistor are different types of transistors.

17. The level shifter for a flat panel display device according to claim 16, wherein:
a source of the third transistor is coupled to the first power supply;
a source of the fourth transistor is coupled to the inverse input voltage terminal; and
a drain of the third transistor and a drain of the fourth transistor are coupled to the output voltage terminal.

18. The level shifter for a flat panel display device according to claim 13, wherein the initial charging part comprises:
a level-up circuit part for receiving a reset signal and an inverse reset signal to level up to a predetermined voltage and output the reset signal and the inverse reset signal; and
a buffer part for stabilizing an output voltage of the level-up circuit part.

19. The level shifter for a flat panel display device according to claim 18, wherein the level-up circuit part comprises:
a first N-channel transistor and a second N-channel transistor for receiving the reset signal and the inverse reset signal; and
a latch circuit for leveling up the input voltage, wherein the latch circuit comprises a first P-channel transistor and a second P-channel transistor.

20. A level shifter for a flat panel display device, the level shifter comprising:
an initial charging part; and
a plurality of level shifter parts individually coupled with the initial charging part,
wherein each of the plurality of level shifter parts comprises:
a first transistor having a gate adapted to receive a signal output from the initial charging part;
a capacitor coupled between an inverse input voltage terminal and a first node coupled to a drain of the first transistor;
a second transistor having a gate coupled to the first node, wherein the second transistor is coupled between a first power supply and an output voltage terminal; and
a third transistor having a gate coupled to the first node, wherein the third transistor is coupled between an input voltage terminal and the output voltage terminal.

21. The level shifter for a flat panel display device according to claim 20, wherein a source of the first transistor is coupled with the first power supply.

22. The level shifter for a flat panel display device according to claim 20, wherein the third transistor and the fourth transistor are different types of transistors.

23. The level shifter for a flat panel display device according to claim 22, wherein:
a source of the third transistor is coupled to the first power supply;
a source of the fourth transistor is coupled to the input voltage terminal; and
a drain of the third transistor and a drain of the fourth transistor are coupled to the output voltage terminal.

24. The level shifter for a flat panel display device according to claim 20, wherein the initial charging part comprises:
a level-up circuit part for receiving a reset signal and an inverse reset signal to level up to a predetermined voltage and output the reset signal and the inverse reset signal; and
a buffer part for stabilizing an output voltage of the level-up circuit part.

25. A level shifter for a flat panel display device, the level shifter comprising:
an initial charging part comprising:
a level-up circuit part for receiving a reset signal and an inverse reset signal to level up to a predetermined voltage and output the reset signal and the inverse reset signal; and
a buffer part for stabilizing an output voltage of the level-up circuit part; and
a plurality of level shifter parts individually coupled with the initial charging part,
wherein each of the plurality of level shifter parts comprises:
a first transistor having a gate adapted to receive a signal output from each of the initial charging parts, wherein the first transistor is coupled between a first node and a ground voltage or a power supply;
a capacitor coupled between the first node and an input voltage terminal or an inverse input voltage terminal;
a second transistor in which the gate is coupled to the first node, and wherein the second transistor is coupled between the power supply and an output voltage terminal; and
a third transistor having a gate coupled to the first node, and coupled at a first end between the inverse input voltage or the input voltage terminal and coupled at a second end to the output voltage terminal.
